(19) United States
(12) Patent Application Publication
(10) Pub. No.: US 2009/0181313 A1
(43) Pub. Date: Jul. 16, 2009

(54) PIGMENT LAYER AND METHOD ESPECIALLY FOR A DURABLE INSCRIPTION OF GLASS USING A HIGH ENERGY RADIATION

(75) Inventors: ARNE KOOPS, (US); SVEN REITER, Hamburg (DE); JOCHEN STAHR, Itzehoe (DE)

Correspondence Address: NORRIS, MCLAUGHLIN & MARCUS, P.A., 875 THIRD AVE, 18TH FLOOR, NEW YORK, NY, 10022, US

(73) Assignee: TESA AG, Hamburg (DE)

(21) Appl. No.: 12/013,588

(22) Filed: Jan. 14, 2008

(51) Int. Cl. G03F 7/004

(52) U.S. Cl. 430/2

(57) ABSTRACT

A pigment layer intended more particularly for the permanent marking of glass, based on a polymer matrix which reacts predominantly with pulverization to a high-energy beam, more particularly to laser irradiation, and comprising at least one titanium compound and free carbon.

The invention relates to a pigment layer and to methods intended more particularly for the permanent scribing of glass by means of high-energy radiation.

For the identity marking of components in vehicles, machinery, electric and electronic devices, or of parts consisting, for example, of glass, one approach is to use technical labels as, for instance, model identification plates, process control labels, guarantee badges, and testing plaquettes.

Also known, particularly in the case of metals or glass, are a variety of scribing methods. Scribing may take place, for example, by means of application of material, such as with ink, or else with removal of material, such as in the case of engraving.

Identity marking by means of laser labels and printed or coated metal plates possesses an increasing status particularly for high-value marking. In this way, information and advice for the subsequent user is located on a wide variety of parts.

By Way of example the label can be scribed with a barcode. A suitable read device provides the option, through the barcode, of reading information concerning the scribed product or its contents.

As well as this standard information, however, sensitive security data are also located by means of labels. In the case of theft, accident or guarantee, this information is very important for the recovery of product and contents.

In addition, this information can also be used to ensure that the scribing takes place directly on the product to be scribed.

Powerful, controllable lasers for burning markings such as writing, coding and the like are widespread. Requirements imposed on the material to be scribed or to be used for scribing include the following:

It should be rapidly scribable.

It should attain a high spatial resolution capacity.

It should be extremely easy to use.

The decomposition products should not have a corrosive action.

The identity marking method should have little or no effect on the mechanical stability of the component.

Furthermore, special cases require additional characteristic features. The symbols produced by laser treatment should be of such high contrast that they can be read faultlessly from far distances even under adverse conditions.

A high level of temperature stability ought to exist, to over 200° C., for example.

High levels of resistance to weathering, water, and solvents are desirable.

If the scribings are to be applied to the component not with a laser label but instead by means of printing, it is an easy possibility for third parties to remove the scribing by washing or rubbing. Moreover, the simple rubbing of the scribed article against a second article, a pack for example, is often enough to weaken the individual letters or numbers.

Glass surfaces are identity-marked typically by the conventional sandblasting technique and laser engraving. The resulting identity marking possesses low contrast and is generated by removing glass material, which entails altering the mechanical stability.

The evaporation of material by means of a laser is known and is referred to as the LTF (Laser Transfer Film) method or as PLD (Pulsed Laser Deposition). With both methods there is a deposition of the evaporated material on the target substrate. The evaporated material enters into a physicochemical bond.

DE 101 52 073 A discloses a laser transfer film for the permanent inscription of components, comprising at least one carrier layer, an adhesive layer being present at least partly on the bottom face of the carrier layer, and a pigment layer being applied at least partially on the carrier layer and/or adhesive layer, said pigment layer comprising at least one laser-sensitive pigment.

Suitable additives are color pigments and metal salts. Pigments from the company Thermark find use more particularly, an example being Thermark 120-30F, which comprises metal oxides, molybdenum trioxide for example. Additionally it is possible to use mixtures of two or more pigments, or blends of pigments and glass particles, of the kind available from the company Merck, which can lead to a sintering process.

The additive may be used further to the additive titanium dioxide.

Moreover, a variety of pigments from the company Merck (examples being the pearlescent pigments EM 143220 and BR 3-01) are suitable.

DE 101 13 112 A1 describes a multilayer laser transfer film for the permanent inscription of components, comprising at least one carrier layer, a first adhesive layer being present at least partly on the bottom face of the carrier layer, and there being at least two pigment layers on the side of the carrier layer of the transfer film on which the first adhesive layer is located.

The pigment layers preferably comprise an at least partly applied first pigment layer, comprising at least one glass flux pigment, and an at least partially applied second pigment layer, comprising at least one laser-sensitive pigment.

In one advantageous embodiment the first pigment layer comprises a glass flux pigment and an absorber, and/or the second pigment layer comprises a glass flux pigment, an absorber, and a laser-sensitive pigment.

DE 102 13 111 A1 discloses a multilayer laser transfer film for the permanent inscription of components, comprising at least one carrier layer, a first adhesive layer being present at least partly on the bottom face of the carrier layer, at least two pigment layers comprising a laser-sensitive pigment being present at least partly on the side of the carrier layer of the laser transfer film on which the first adhesive layer is located, and the concentrations of the laser-sensitive pigment in the pigment layers being different.

U.S. Pat. No. 6,313,436 B describes a heat-fed chemical marking method comprising the steps of:
a) applying a layer of mixed metal oxide to a metal substrate,
b) said layer comprising an energy absorption enhancer,
c) irradiating said layer with an energy beam to match the form of the marking to be applied,
d) the energy beam having a wavelength selected to excite the energy absorption enhancer,
e) thereby forming a marking layer atop the substrate.

It is an object of the invention to provide a pigment layer intended more particularly for the permanent inscription of glass, which allows the rapid and precise scribing of, more particularly, glass; which meets the stated requirement of improved anticounterfeit security; which is applied in a way which is benign for the component; which cannot be removed nondestructively; which, additionally and more particularly, features high contrast, high resolution capacity, and high temperature resistance; and which is easy to employ.

This object is achieved by means of a pigment layer as described in the main claim. The dependent claims provide particularly advantageous embodiments of the subject matter of the invention, the use thereof, and methods of scribing glass.

The invention accordingly provides a pigment layer intended more particularly for the permanent marking of glass, based on a polymer matrix which reacts predominantly with pulverization to a high-energy beam, more particularly to laser irradiation, and comprising at least one titanium compound and free carbon.

According to a first advantageous embodiment of the invention the titanium compound is titanium dioxide, preferably in rutile structure, the latter being one of the four crystal polymorphs of titanium dioxide.

Rutile pigments have a refractive index, n, of 2.75 and absorb fractions of visible light even at wavelengths around 430 nm. They have a hardness of 6 to 7.

With further preference the free carbon is formed by carbon black. The free carbon may also originate from the polymer matrix decomposed, evaporated, oxidized, depolymerized and/or pyrolyzed on laser exposure.

Preference is given to using neutral carbon black with a pH from 6 to 8. Preferred suitability is possessed predominantly by thermal black, acetylene black, and lamp black. Lamp black is particularly preferred. The pH values of lamp black are typically 7 to 8, those of thermal black 7 to 9, and those of acetylene black 5 to 8. Furnace blacks are situated typically at 9 to 11 and are therefore very basic. Oxidized gas blacks are situated typically at 2.5 to 6 and are therefore very acidic.

Their use in accordance with the invention, however, is not ruled out.

The stated pigment blacks are extremely resistant to chemicals and are distinguished by high lightfastness and weathering resistance. On account of the very high depth of color and color strength, and also of other specific properties, pigment blacks are the most frequently used black pigments.

Pigment blacks are manufactured industrially by thermooxidative or thermal cleavage of hydrocarbons. Pigment blacks are produced almost exclusively by the furnace black process, Degussa gas black process, and lamp black process.

According to another advantageous embodiment of the invention the polymer matrix is a radiation-cured polymer matrix.

The polymer matrix is composed advantageously of a varnish, more particularly of a cured varnish, preferably a radiation-cured varnish, with particular preference an electron-beam-cured aliphatic, difunctional polyurethane acrylate varnish. In one alternative embodiment the carrier layer is a polyester acrylate.

There are in principle four types of varnish which can be used for the polymer matrix in accordance with the invention, provided their stability is sufficient: for example, acid-curing alkyd-melamine resins, addition-crosslinking polyurethanes, free-radically curing styrene varnishes, and the like. Particular advantage, however, is possessed by radiation-curing varnishes, on account of their very rapid curing without lengthy evaporation of solvents or the action of heat. Varnishes of this kind have been described, for example, by A. Vrancken (Farbe und Lack 83, 3 (1977) 171).

According to one particularly advantageous embodiment of the invention the composition of the pigment layer is as follows:
100 phr polymer matrix, more particularly a radiation-cured aliphatic, difunctional polyurethane acrylate,
0.2 to 2.5 phr carbon black, and
45 to 65 phr titanium dioxide.

“phr” denotes “parts per hundred resin”, a unit commonplace in the polymer industry for the purpose of characterizing compositions of mixtures, with all of the polymeric ingredients (in this case, therefore, the polymer matrix) being set at 100 phr.

With further preference the composition is as follows:
100 phr polymer matrix, more particularly a radiation-cured aliphatic, difunctional polyurethane acrylate,
0.4 phr carbon black, and
63.2 phr titanium dioxide.

The thickness of the pigment layer may lie within a range from 20 to 500 μm, more particularly 30 to 100 μm, in order to meet with outstanding effect the requirements imposed on it.

The properties can be optimized by blending the pigment layer with one or more additives such as plasticizers, fillers, pigments, UV absorbers, light stabilizers, aging inhibitors, crosslinking agents, crosslinking promoters or elastomers.

When the high-energy beam, more particularly a laser beam, strikes the pigment layer, said layer is disintegrated essentially into small particles in the region of the point of strike, so that the pulverized material removed from the pigment layer by laser-generated burning has a number-average particle size of 0.5 to 2.0 μm.

When irradiation is carried out using high-energy radiation such as laser radiation, in the form for example of a laser pulse, the radiation or laser light comes directly into contact or interaction with the pigment layer surface, and, as a result of the laser light striking the layer, the laser light is converted into heat, which acts on the surface.

The laser beam is coupled into the material by absorption. The absorption has the effect that material is evaporated, that particles are extracted, and a plasma may form. Particularly at the margins of the laser beam exposure there are thermal melting processes.

Typically, when the laser energy is converted into heat, long-chain polymer constituents of the pigment layer are cleaved, and one of the products of thermal cracking is elemental carbon.

In summary, the polymer matrix undergoes particulation/evaporation/decomposition as a result of the high energy input of the laser radiation.

The aforesaid carbon is deposited in the form of titanium carbide on the product to be scribed.

The emission constituents at the time of scribing are therefore the elemental carbon, the TiO₂, and the cracking products from the polymer matrix of the pigment layer.

The following reaction may reflect the process, which can be described as a carbothermal synthesis reaction for the preparation of titanium carbide.

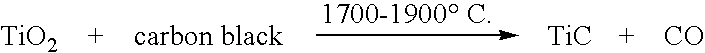

The energy input is determined by the absorption characteristics of the reactants, the type of laser, and its parameterization. Control is exerted primarily by the laser output and scribing speed.

Titanium carbide is a member of the nonoxide ceramics. Nonoxide ceramics are distinguished by higher covalent and lower ionic bonding components, with high chemical and thermal stability, as compared with the silicate ceramics and oxide ceramics. Industrial titanium carbide contains around 19.5% by mass of bonded carbon and up to 0.5% by mass of unbonded carbon, referred to as free carbon.

The theoretical stoichiometric carbon content is 20.05% by mass.

The properties of titanium carbide compound (TiC) are as follows:

| | |
|---|---|
| Color: | gray metallic |
| Melting point: | 3157° C. |
| Density: | 4.93 g/cm³ |
| Crystal | cubic, possessing closest sphere packing, when all of the |
| structure: | octahedral gaps are filled: TiC |

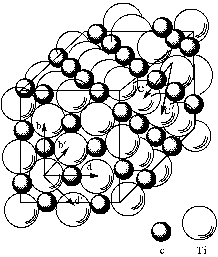

The advantages are:
relatively high hardness and hence resistance to abrasion and wear
extremely high heat resistance
corrosion resistance
high biocompatibility
ferroelectric properties
low thermal conductivity (when the carbon fraction is high)
electrical semiconduction
resistance to cold acids and alkalis

As a result of the formation of inclusion compounds or interstitial compounds, it is possible for small carbon atoms to be intercalated at lattice interstices or spaces in the crystal lattice, these atoms then giving titanium carbide a black color. This also results, ultimately, in the high-contrast black scribe marking on the product to be scribed.

In other words, the very high-contrast scribe marking on the product to be scribed comes about as a result of the fact that titanium carbide is deposited on the product, the gaps in the crystal lattice being penetrated by free carbon atoms which originate, for example, from the carbon black or from cracked elemental carbon from the polymer matrix.

According to another advantageous embodiment of the invention the pigment layer is coated partly or over its whole area with an adhesive, more particularly a pressure-sensitive adhesive.

The adhesive layer may more particularly be applied in the form of dots or in screen printing, where appropriate also in the form of marginal printing, so that the pigment layer can be bonded in any desired way to the substrate.

The adhesive in question is preferably a pressure-sensitive adhesive.

The pigment layer is coated on one or both sides with the preferred pressure-sensitive adhesive, in the form of a solution or dispersion or in 100% form (as a melt, for example). The adhesive layer or layers can be crosslinked by means of heat or high-energy beams and, where necessary, can be lined with release film or release paper. Suitable pressure-sensitive adhesives are described in D. Satas, Handbook of Pressure Sensitive Adhesive Technology (Van Nostrand Reinhold). Suitability is possessed more particularly by pressure-sensitive adhesives based on acrylate, natural rubber, thermoplastic styrene block copolymer or silicone.

In order to optimize the properties, it is possible for the self-adhesive composition employed to have been blended with one or more additives such as tackifiers (resins), plasticizers, fillers, pigments, UV absorbers, light stabilizers, aging inhibitors, crosslinking agents, crosslinking promoters or elastomers.

Suitable elastomers for blending are, for example, EPDM or EPM rubber, polyisobutylene, butyl rubber, ethylene-vinyl acetate, hydrogenated block copolymers comprising dienes (for example, through hydrogenation of SBR, cSBR, BAN, NBR, SBS, SIS or IR; such polymers are known, for example, as SEPS and SEBS) or acrylate copolymers such as ACM.

Tackifiers are, for example, hydrocarbon resins (for example, from unsaturated C₅ or C₇ monomers), terpene-phenolic resins, terpene resins from raw materials such as α-pinene or β-pinene, aromatic resins such as coumarone-indene resins, or resins formed from styrene or α-methylstyrene, such as rosin and its derivatives, such as disproportionated, dimerized or esterified resins, the use of glycols, glycerol or pentaerythritol being possible, and also others, as listed in Ullmanns Enzyklopädie der technischen Chemie, volume 12, pages 525 to 555 (4^{th} edition), Weinheim. Particularly suitable are resins which are stable to aging and have no olefinic double bond, such as hydrogenated resins, for example. Examples of suitable plasticizers are aliphatic, cycloaliphatic, and aromatic mineral oils, diesters or polyesters of phthalic acid, trimellitic acid or adipic acid, liquid rubbers (for example, nitrile rubbers or polyisoprene rubbers), liquid polymers of butene and/or isobutene, acrylic esters, polyvinyl ethers, liquid resins and plasticizer resins based on the raw materials for tackifier resins, wool wax and other waxes, or liquid silicones.

Examples of crosslinking agents are phenolic resins or halogenated phenolic resins, melamine resins, and formaldehyde resins. Suitable crosslinking promoters are, for example, maleimides, allyl esters such as triallyl cyanurate, and polyfunctional esters of acrylic and methacrylic acid.

The thickness of coating with adhesive is preferably in the range from 5 to 100 g/m², more particularly 10 to 25 g/m².

With further preference the pigment layer may be applied on a carrier, preferably on a carrier sheet, the pigment layer being coated onto said sheet.

In accordance with the invention the carrier sheet used may preferably comprise films which are transparent, more particularly monoaxially and biaxially oriented films based on polyolefins, in that case films based on oriented polyethylene or oriented copolymers containing ethylene units and/or polypropylene units, and also, where appropriate, PVC films, and films based on vinyl polymers, polyamides, polyester, polyacetals or polycarbonates.

PET films are outstandingly suitable, more particularly, as carriers.

Films based on oriented polyethylene or oriented copolymers containing ethylene units and/or polypropylene units can also be used as a carrier sheet in accordance with the invention.

Further preference is given to single-ply biaxially or monoaxially oriented films and multiply biaxial or monoaxial films based on polypropylene.

Films based on unplasticized PVC are used, as are films based on plasticized PVC. Polyester-based films, such as polyethylene terephthalate, for example, are likewise known and can also be used.

It is also possible for parts of the pigment layer to have been deactivated by means of a partially applied passivating layer, on the side which, during the marking operation, is in contact with the substrate.

The pigment layer with or without carrier sheet and/or adhesive coating and with all further layers may for the purposes of this invention be present in the form of all sheetlike structures, such as two-dimensionally extended films or film sections, tapes with extended length and limited width, tape sections, diecuts, labels, and the like.

Also possible is the winding of a comparatively long pigment layer to form an archimedean spiral, from which a section of desired length is separated off for use in each case.

The pigment layer can be employed with particular advantage for the marking of glass. The reason for this is that, with glass in particular, all of the advantages of the pigment layer of the invention that come about when the pigment layer is used to scribe glass are exploited.

The scribing outcome achieved is very good. Moreover, the level of fume generated is surprisingly low. Immediately after the scribing process, the indicia have a very high contrast. The unfixed residue can be removed by dry or wet wiping of the surface of the identity marking.

Particularly when the standard lasers are used, more especially the widespread Nd-YAG solid-state lasers with a wavelength of 1.06 μm, the scribe markings and identity markings obtained are sharp and of high contrast.

With further preference the applied marking is an interference hologram, since the quality of resolution of the process allows structures for the amplification and extinction of light.

With further preference the pigment layer of the invention can be used in a method of marking glass, the pigment layer being brought by pressing into direct contact with the glass substrate to be scribed, the pigment layer being irradiated with a laser, the laser beam interacting with the pigment layer through the glass to be scribed, and the marking being developed on the side of the glass remote from the laser source.

The direct contact between pigment layer and glass article avoids an interspace which leads to an enlargement of the reaction space during laser irradiation. The consequence of that would be to allow the deposit on the glass substrate to be distributed over a larger surface area, so lessening the definition of the resulting scribe marking.

The surface to be scribed is preferably cleaned before the pigment layer is applied.

In addition it is advantageous, in accordance with the invention, for residues and/or the pigment layer no longer needed to be removed from the surface after the high-energy beam has been applied.

It is particularly advantageous if the pigment layer is applied substantially only to regions of the surface that are subsequently to be scribed or marked.

Preference is given to using a diode-pumped solid-state laser where the pulse duration of the laser is between 40 and 90 ns, the initial output is 20 watts and/or the scribing rate is 250 to 750 mm/sec, depending on the content of the scribe marking.

Where the target substrate is glass, the transmission technique is possible, since the wavelength of 1.064 μm that is used is transparent for glass.

The scribe marking which comes about in the glass has a height of 0.25 to 3.0 μm, depending on the content of the scribe marking and on the parameterization.

The temperature stability has been shown to be in the range from −50° C. to 1200° C. The low-temperature resistance and heat resistance, however, are substantially higher. The mechanical resistance with respect to abrasion is extremely high (crockmeter test>1000 strokes).

The scribe marking exhibits a high accuracy of resolution, depending on the beam quality used; the line width is 70 μm to 80 μm.

In accordance with the invention it is possible to produce machine-readable 2D codes with an edge length of 1.5×1.5 mm and a content of 16 characters.

Moreover, it is possible to realize all of the typical content of identity markings, such as logos, pictograms, drawings, alphanumeric symbols, special symbols, and pixel graphics.

The invention also embraces, finally, a glass article marked using the pigment layer of the invention.

The term “glass article” encompasses sheets, containers or tubes, and glass surfaces of generally convex or concave form.

In the text below an example is used to illustrate the composition of a polymer layer in more detail, without any restrictive effect whatsoever:

| Substrate | Fraction [phr] |
|---|---|
| EB 284 | 85.1 |
| HDDA | 5.0 |
| DVE 3 | 9.9 |
| Carbon black | 0.4 |
| Titanium dioxide | 63.2 |
| Sum total | 163.6 |

EB 284: aliphatic, difunctional polyurethane acrylate (manufacturer: Cytec)
HGDDA: hexanediol diacrylate (manufacturer: BASF)
DVE 3: divinyl ether (manufacturer ISP or BASF)
Carbon black: (manufacturer: Evonik, Printex 25)
TiO₂: (manufacturer: Kronos, Kronos 2160)

Printex 25 is a furnace black, particle size 56 nm, surface area 45 m²/g.

The composition is coated out to give a layer having a thickness of 100 μm.

Sections measuring 30×50 mm are produced from the applied coat by punching.

Finally, using a number of figures, the use of the polymer layer of the invention for scribing a glass article, in one advantageous embodiment, is illustrated in more detail, without any intention to thereby restrict the invention unnecessarily.

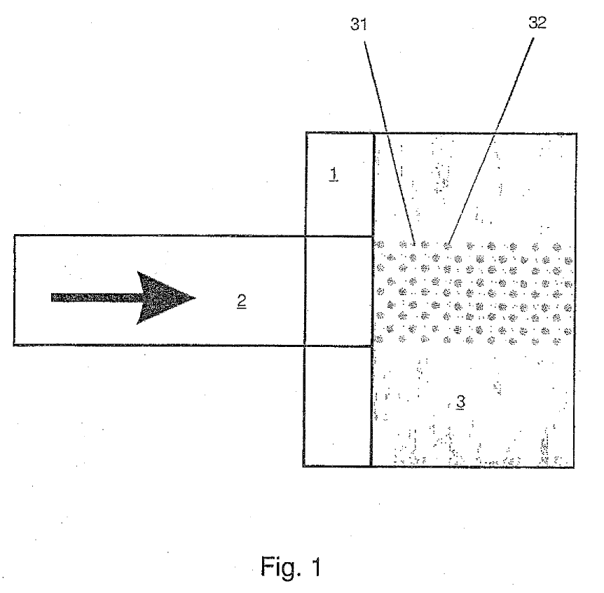

FIG. 1 shows the scribing of a glass article by means of a laser using the transmission technique and the polymer layer of the invention;

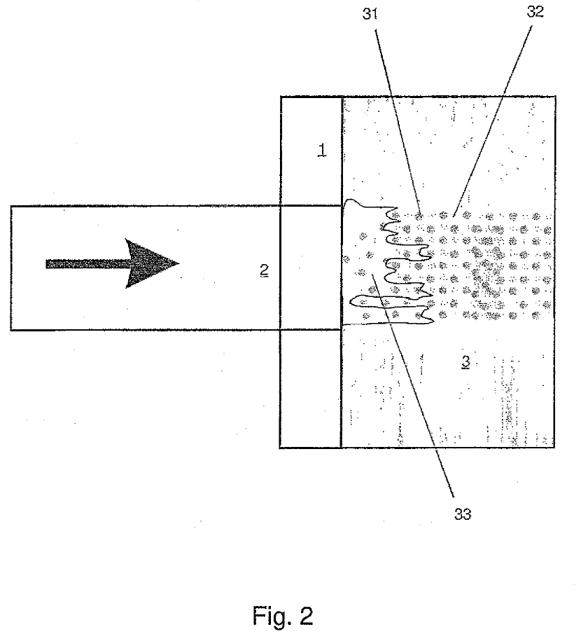

FIG. 2 shows the process of evaporation of the matrix of the polymer layer at the point where the laser strikes; and

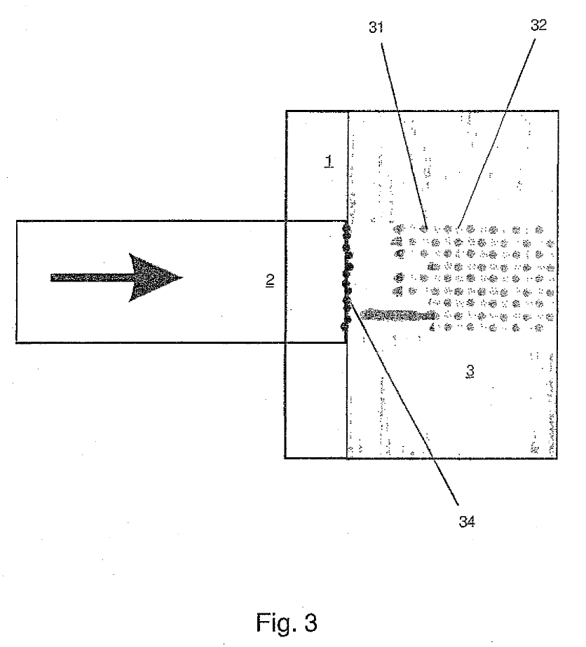

FIG. 3 shows the formation of the scribe marking on the glass article by titanium carbide.

FIG. 1 shows the scribing of a glass article 1 by means of a laser which emits a laser beam 2, using the transmission technique and the polymer layer 3 of the invention.

The laser used is an Nd:YAG laser having a wavelength of 1.064 μm which is transparent for the glass article 1. The laser 2 therefore passes through the glass article 1 and strikes the polymer layer 3, which is in direct contact with the glass article 1.

The polymer layer 3 is composed of the polymer matrix with the titanium dioxide 31 and carbon black 32 incorporated in it by mixing.

FIG. 2 shows the process of the evaporation, with pulverization beforehand, of the matrix of the polymer layer at the point where the laser strikes. The striking of the laser light 2 on the matrix converts the laser light 2 into heat, which acts on the surface of the polymer layer 3. The matrix, as a result of absorption of the laser light 2, is converted locally into a plasma 33, also called a plasma cloud.

As a result of the formation of the plasma 33 a reaction takes place between the titanium dioxide 31 and the carbon black 32, to give titanium carbide 34, which, as shown in FIG. 3, is deposited on the surface of the glass article 1.

1. A pigment layer for the permanent marking of glass, based on a polymer matrix which reacts predominantly with pulverization to laser irradiation, and comprising at least one titanium compound and free carbon.

2. The pigment layer as claimed in claim 1, wherein the titanium compound is titanium dioxide.

3. The pigment layer as claimed in claim 1, wherein the free carbon is formed by carbon black and/or originates from the polymer matrix decomposed, evaporated, oxidized, depolymerized and/or pyrolyzed on laser exposure.

4. The pigment layer as claimed in claim 1, wherein the polymer matrix is a radiation-cured polymer matrix.

5. The pigment layer as claimed in claim 1, having the following composition:
100 phr radiation-cured aliphatic, difunctional polyurethane acrylate, 0.2 to 2.5 phr carbon black, and 45 to 65 phr titanium dioxide.

6. The pigment layer as claimed in claim 1, having a thickness in a range from 20 to 500 μm.

7. The pigment layer as claimed in claim 1, which has had pulverized material having a number-average particle size of 0.5 to 2.0 μm is removed from the pigment layer by laser-generated burning.

8. The pigment layer as claimed in claim 1, being coated partially or over its whole area with an adhesive.

9. The pigment layer as claimed in claim 1, applied on a carrier.

10. The pigment layer as claimed in claim 1, deactivated by a partially applied passivating layer, on the side which is to be brought into contact with a substrate during a marking operation.

11. A method for marking glass, which comprises applying the pigment layer of claim 1 to said glass and irradiating said pigment layer with a laser.

12. The method of claim 11, wherein an interference hologram is formed on said glass by said method.

13. The method of claim 11, wherein the pigment layer is brought by pressing into direct contact with the glass to be marked, the pigment layer is irradiated with a laser, the laser beam interacting with the pigment layer through the glass, and the marking is developed on the side of the glass remote from the laser source.

14. The method as claimed in claim 13, wherein the pulse duration of the laser lies between 40 and 90 ns.

15. A glass article having markings formed with the pigment layer claim 1.

16. The pigment layer as claimed in claim 2, wherein the free carbon is formed by carbon black and/or originates from the polymer matrix decomposed, evaporated, oxidized, depolymerized and/or pyrolyzed on laser exposure.

17. The pigment layer as claimed in claim 8, wherein said adhesive is a pressure-sensitive adhesive.

18. The pigment layer of claim 9, wherein said carrier is a carrier sheet.
